(19) United States
(12) Patent Application Publication
(10) Pub. No.: US 2026/0029460 A1
(43) Pub. Date: Jan. 29, 2026

(54) CROSSTALK CANCELLATION VIA POLARITY CONTROL OF DIFFERENTIAL SIGNAL CONTACTS

(71) Applicant: Credo Technology Group Limited, George Town (KY)

(72) Inventors: Xike Liu, Santa Clara, CA (US); Xin Wang, Shanghai (CN); Dennis Nguyen, Morgan Hill, CA (US); Trung Hua, San Jose, CA (US); Heng Chen, Wuhan (CN); Thomas Nguyen, San Jose, CA (US)

(73) Assignee: Credo Technology Group Limited, George Town (KY)

(21) Appl. No.: 18/819,952

(22) Filed: Aug. 29, 2024

Related U.S. Application Data
(60) Provisional application No. 63/675,352, filed on Jul. 25, 2024.

(51) Int. Cl. G01R 31/28; G01R 1/073

(52) U.S. Cl. CPC G01R 31/2831; G01R 1/07357

(57) ABSTRACT

Connectors to a set of differential transmit signal contacts for multiple lanes of a communications link may incur signal crosstalk between adjacent lanes. Similar signal crosstalk at the other end of the communications link may be incurred by connectors to a set of differential receive signal contacts. The connector arrangement may provide opposite polarities to the signal crosstalk contributions at opposite ends of the link, creating a substantial reduction in crosstalk.

### FIELD

The present disclosure relates to interface connections for high bandwidth multi-lane communications links, and more particularly to integrated circuit contact layouts that reduce crosstalk by arranging differential signal polarities to cause crosstalk cancellation at opposite ends of the link.

### BACKGROUND

Wafer probe testing systems are an important part of the semiconductor manufacturing process, enabling electrical verification and characterization of the integrated circuit (IC) dies at the wafer level. These systems facilitate early defect detection before wafers proceed to dicing and packaging. In IC dies having high-density, high bandwidth contact configurations, probe testing may be hampered by the issue of far-end crosstalk (FEXT), which most commonly appears as electromagnetic interference between adjacent lanes of a communications link. The high-density requirements often preclude the inclusion of ground (GND) bumps between closely spaced transmit and receive contacts for adjacent lanes, an arrangement that would otherwise be useful for reducing crosstalk.

Wafer probe testers typically rely on long probe needles, which can be several millimeters in length, to connect the probe card to the wafer contacts. The probe needles have the same pitch as the contacts on the wafer, further exacerbating the crosstalk problem. It has been observed that the crosstalk incurred by the test probe assembly significantly degrades communications link signal quality and impairs the testing process.

### SUMMARY

Accordingly, there are disclosed herein integrated circuits, systems, and testers, employing polarity control of differential signal contacts to reduce signal crosstalk between lanes. One illustrative integrated circuit die includes: a first pair of differential transmit signal contacts for a first lane of a communications link; a second pair of differential receive signal contacts for the first lane of the communications link; a first adjacent pair of differential transmit signal contacts for a second lane of the communications link adjacent to the first lane; and a second adjacent pair differential receive signal contacts for the second lane of the communications link. The first pair and the first adjacent pair incur signal crosstalk with a first polarity, and the second pair and the second adjacent pair incur signal crosstalk with a second polarity opposite of the first polarity.

One illustrative system includes: a first integrated circuit die having a set of differential transmit signal contacts for multiple adjacent lanes of a communications link; a second integrated circuit die having a set of differential receive signal contacts for the multiple adjacent lanes; a first set of connectors coupling the differential transmit signal contacts to a set of conductors; and a second set of connectors coupling the set of conductors to corresponding differential receive signal contacts. The first set of connectors introduces signal crosstalk of a first polarity between a first lane of the multiple adjacent lanes and a first adjacent lane of the multiple adjacent lanes, and the second set of connectors introduces signal crosstalk of a second polarity between the first lane and the first adjacent lane, the second polarity being opposite of the first polarity.

An illustrative wafer tester includes: a substrate; and a test probe head mounted on the substrate having needles configured to connect bumps of an integrated circuit on a wafer to traces on the substrate. The bumps include: a first pair of differential transmit signal contacts for a first lane of a communications link; a second pair of differential receive signal contacts for the first lane of the communications link; a first adjacent pair of differential transmit signal contacts for a second lane of the communications link adjacent to the first lane; and a second adjacent pair differential receive signal contacts for the second lane of the communications link. The needles contacting the first pair and first adjacent pair introduce signal crosstalk of a first polarity, the needles contacting the second pair and second adjacent pair introduce crosstalk of a second polarity, and the traces on the substrate configure the second polarity to be opposite of the first polarity during loopback testing.

Each of the foregoing may be implemented individually or conjointly, together with any one or more of the following features in any suitable combination. 1. the first pair of differential transmit signal contacts has a signal polarity that matches a signal polarity of the first adjacent pair of differential transmit signal contacts. 2. the second pair of differential receive signal contacts has a signal polarity that is reversed relative to a signal polarity of the second adjacent pair of signal contacts. 3. the first pair of differential transmit signal contacts has a signal polarity that is reversed relative to a signal polarity of the first adjacent pair of differential transmit signal contacts. 4. the second pair of differential receive signal contacts has a signal polarity that matches a signal polarity of the second adjacent pair of signal contacts. 5. a pair of differential transmit signal contacts for each lane of the communications link, the pairs of differential transmit signal contacts having a matching signal polarity for adjacent lanes. 6. a pair of differential receive signal contacts for each lane of the communications link, the pairs of receive signal contacts having opposite signal polarities for adjacent lanes. 7. a pair of differential transmit signal contacts for each lane of the communications link, the pairs of differential transmit signal contacts having opposite signal polarities for adjacent lanes. 8. a pair of differential receive signal contacts for each lane of the communications link, the pairs of receive signal contacts having matching signal polarities for adjacent lanes. 9. the first integrated circuit die is also the second integrated circuit die. 10. the set of conductors are part of a test probe card configured to provide loopback testing. 11. the first set of connectors and the second set of connectors are probe needles configured to contact bumps on the first integrated circuit die. 12. the first set of connectors and the second set of connectors include bumps or pins connecting the first integrated circuit die and the second, different integrated circuit die to printed circuit traces on a substrate.

### BRIEF DESCRIPTION OF THE DRAWINGS

FIG. 1 shows a top view of an illustrative wafer with multiple integrated circuit dies.

FIG. 2 is a cross-sectional view of a probe head assembly used for wafer testing.

FIG. 3 is a layout diagram of an illustrative arrangement of transmit, receive, and ground signal contacts on a die.

FIG. 4A is a schematic diagram showing illustrative connections between contacts for differential transmit and receive signals.

FIG. 4B is a perspective view of illustrative printed circuit trace connections between sets of probe head connectors.

FIG. 5A is a schematic diagram showing illustrative connections with a swapped polarity between adjacent lanes.

FIG. 5B is a perspective view of illustrative printed circuit trace connections suitable for the swapped polarity arrangement of FIG. 5A.

FIG. 6 is a graph of simulated crosstalk between lanes comparing a conventional arrangement of differential signal contacts with a swapped polarity arrangement.

FIG. 7 is a layout diagram of an illustrative arrangement of differential signal contacts with alternating receive signal polarity.

FIG. 8 is a layout diagram of an illustrative arrangement of differential signal contacts with alternating transmit signal polarity.

FIG. 9 is a function block diagram of an illustrative integrated circuit that supports multi-lane communication links.

### DETAILED DESCRIPTION

Note that the specific embodiments given in the drawings and following description do not limit the disclosure. On the contrary, they provide the foundation for one of ordinary skill to discern the alternative forms, equivalents, and modifications that are encompassed in the claim scope.

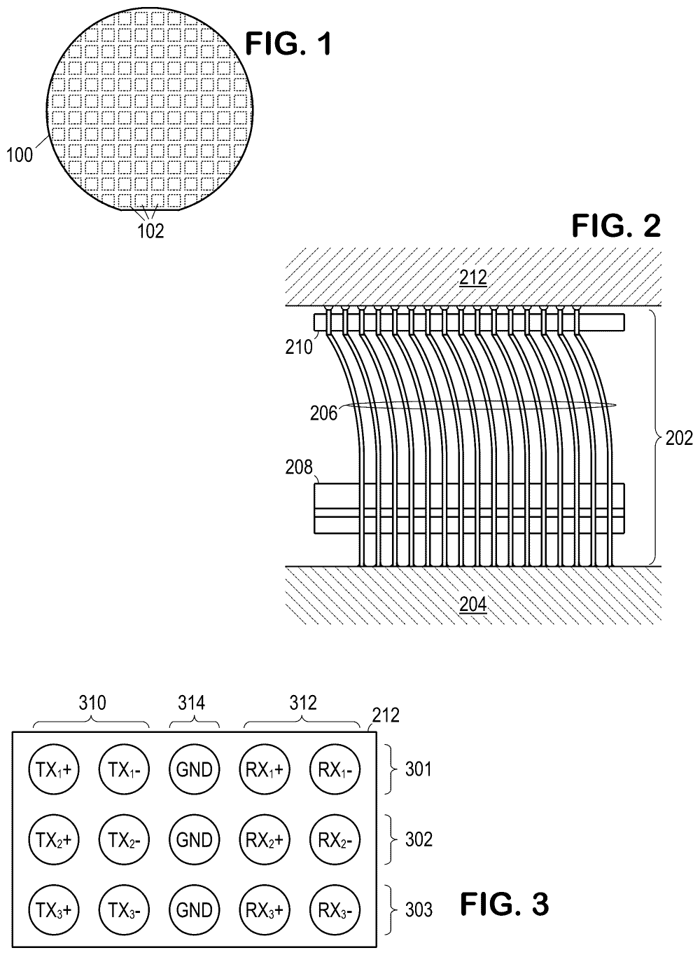

FIG. 1 shows a top view of a wafer 100, which contains multiple dies 102. Each die 102 represents an individual semiconductor device fabricated within the wafer 100. The arrangement of multiple dies 102 upon the wafer 100 facilitates the efficient testing and subsequent dicing of the wafer 100 into individual semiconductor units.

Turning to FIG. 2, the figure depicts a sectional view of a probe head 202 utilized in the wafer testing phase of manufacturing. The probe head 202 is mounted to a substrate 204, which may also be termed probe card 204. To support the closely spaced printed circuit traces for conveying high bandwidth signals, substrate 204 may be a multilayer organic (MLO) laminate rather than a conventional printed circuit board (PCB) composite material. The probe head 202 includes a set of probe needles 206, which are configured to touch electrical contacts on the integrated circuit die under test 212. The electrical contacts may be pads, pins, balls, bumps, or other suitable structures for connecting the integrated circuit die to its intended substrate or package connectors. Each needle connects to a trace or via on the probe card 204 to convey the signals needed for the testing process to or from the respective contact points on the wafer.

Testing may be performed by aligning the die under test 212 with the probe head 202 and pressing it into contact. The needles 206 are shaped to accommodate a degree of height variation in the electrical contacts. The probe head 202 includes both an upper ceramic 210 and a lower ceramic 208, which align and secure the probe needles 206, ensuring precise yet compliant contact with the die under test 212. This configuration allows the electrical connectivity required for thorough examination of the die's functionality.

FIG. 3 shows an enlarged view of the relevant portion of the contact layout for the die under test 212. The die under test 212 provides contacts for multiple lanes of a communications link. Three lanes 301, 302, 303, are shown here, though in practice the number of lanes may be greater or fewer. The illustrated contacts are arranged in three groups, with differential transmit signal contacts 310 separated from differential receive signal contacts 312 by a group of ground contacts 314. The differential transmit signal contacts 310 are labeled as TX1+, TX1− for the first lane 301, TX2+, TX2− for the second lane 302, and TX3+, TX3− for the third lane 303. The differential receive signal contacts are labeled as RX1+, RX1− for the first lane 301, RX2+, RX2− for the second lane 302, and RX3+, RX3− for the third lane 303.

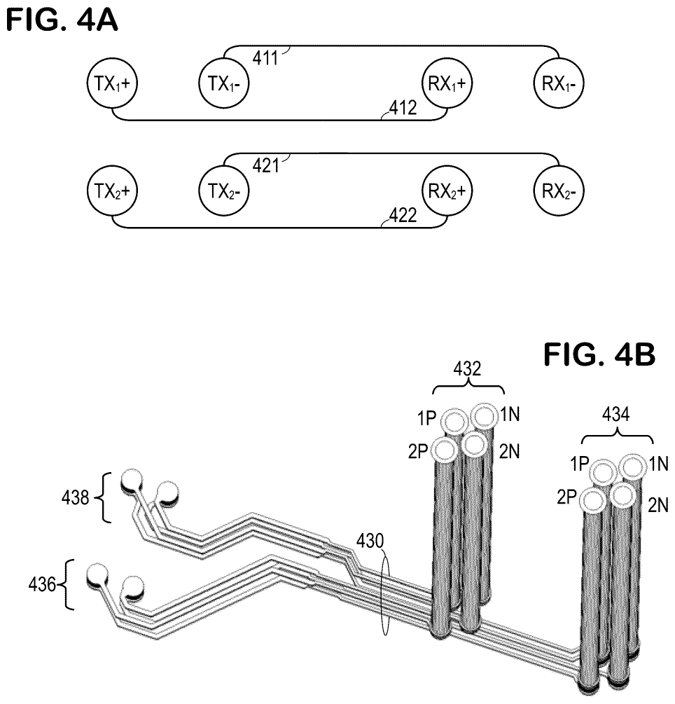

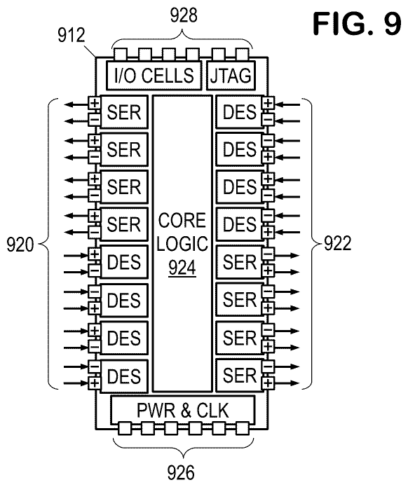

FIG. 4A shows the electrical connections that may be made for two adjacent lanes of a communications link. Conductive path 411 connects transmitter contact TX1− to receiver contact RX1−. Similarly, conductive path 412 connects TX1+to RX1+. In the adjacent lane, conductive path 421 connects the transmitter contact TX2− to the receiver contact RX2−, and conductive path 422 connects TX2+to RX2+. This arrangement is sufficient for loopback testing, where a device's transmit terminals are connected to its own receive terminals. In actual usage, each lane would have a differential signal conveying information in each direction, i.e., from the local device's transmit contacts to the remote device's receive contacts and also from the remote device's transmit contacts to the local device's receive contacts. This usage is discussed further in connection with FIG. 9.

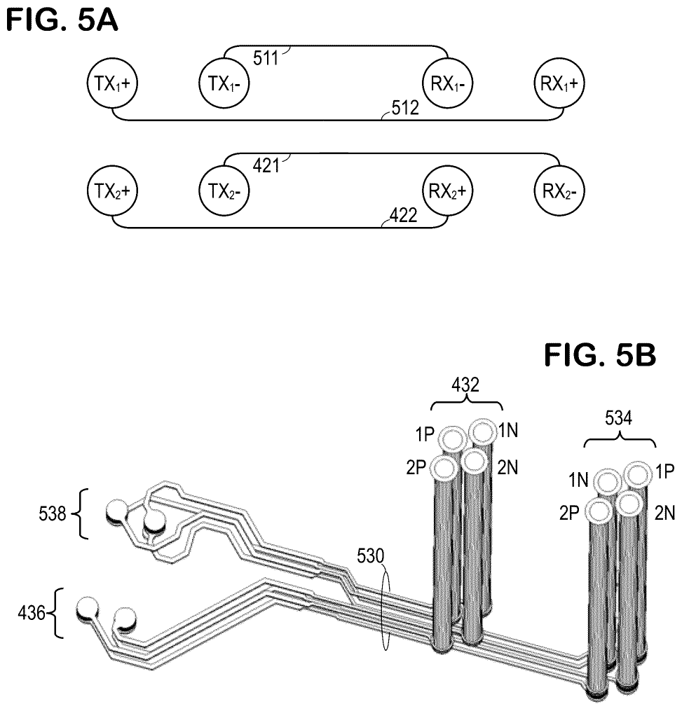

In a test probe assembly configured for loopback testing, the schematic connections of FIG. 4A may be physically implemented as shown in FIG. 4B. (Note, however, FIG. 4B is from a simulation model that simplifies the shape of the needles.) Substrate 204 includes a set of printed circuit traces 430 to provide conductive paths 411-422. Needles 432 form a first set of electrical connections between differential transmit signal contacts TX1+ (abbreviated as 1P), TX1− (1N), TX2+ (2P), TX2− (1N) and respective traces 430. Needles 434 form a second set of electrical connections between the respective traces and the differential receive signal contacts RX1+ (1P), RX1− (1N), RX2+ (2P), RX2− (2N). FIGS. 4B and 5B do not explicitly distinguish transmit and receive contacts, as their roles can be interchanged.

Traces 430 include traces in two different metallization layers of substrate 204. Needles 432 connect to an upper metallization layer. Needles 434 connect to a lower metallization layer. The upper- and lower-layer traces are connected by vias 436 (for lane 2) and vias 438 (for lane 1). Traces 430 do not follow a shortest route between needles 432, 434, but instead incorporate additional length to better represent the attenuation and signal degradation that would typically be encountered in a real-world application environment.

As the differential transmit signals for lanes 1 and 2 traverse needles 432, the signals incur signal crosstalk between the lanes. As the differential signals traverse needles 434 to reach the differential receive signal contacts, they incur additional crosstalk. With the configuration of FIGS. 4A-4B, these crosstalk contributions are additive.

FIG. 5A is a schematic diagram like that of FIG. 4A but with an adjustment to the relative orientation of the differential receive contacts for the two lanes. Probe needle 206 connects transmitter contact TX1− with receiver contact RX1−, and conductive path 512 connects transmitter contact TX1+ to receiver contact RX₁+. The contacts and conductive paths for lane 2 are unchanged relative to FIG. 4A.

The adjusted layout may be implemented as shown in FIG. 5B. Needles 534 are physically the same as needles 434, but the 1P, 1N labels for lane 1 have been swapped. To accommodate this polarity change traces 530 and conductive paths 411 have been adjusted to maintain the 1P-to-1P connection and 1N-to-1N connection.

As before, when the differential transmit signals for lanes 1 and 2 traverse needles 432, the signals incur signal crosstalk between the lanes. As the differential signals traverse needles 534 to reach the differential receive signal contacts, they incur additional crosstalk. However, the reversal of lane 1's receive signal contacts relative to lane 2's receive signal contacts causes this additional crosstalk to have a polarity that is opposite the signal crosstalk from needles 432. When combined, these contributions at least partially cancel each other, reducing the signal crosstalk between lanes.

A similar result can be achieved by swapping the signal polarity of the differential receive signal contacts for lane 2 rather than lane 1. Alternatively, the signal polarity of the differential transmit signal contacts for lane 1, or for lane 2, could be swapped to ensure the crosstalk contribution from one end of the link has the opposite sign as the crosstalk contribution from the other end of the link. Where multiple adjacent lanes are present, adjusting the arrangement of the middle lane will achieve crosstalk reduction from the adjacent lanes on both sides. For four or more lanes, adjusting a connection polarity for each of the odd-numbered (or alternatively, for each of the even-numbered) lanes will be effective at reducing connection-induced crosstalk between all adjacent lane pairs in the link.

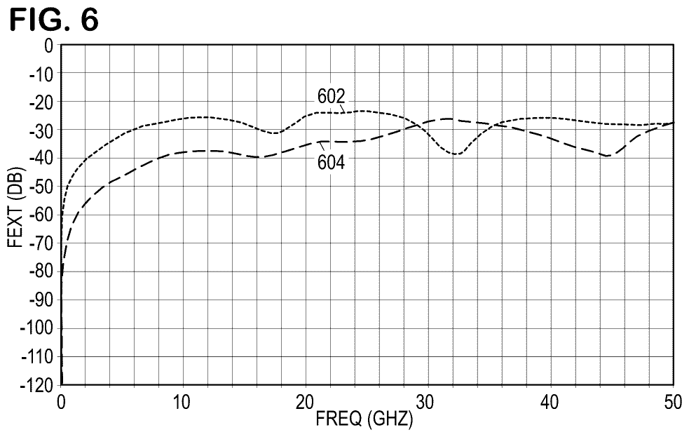

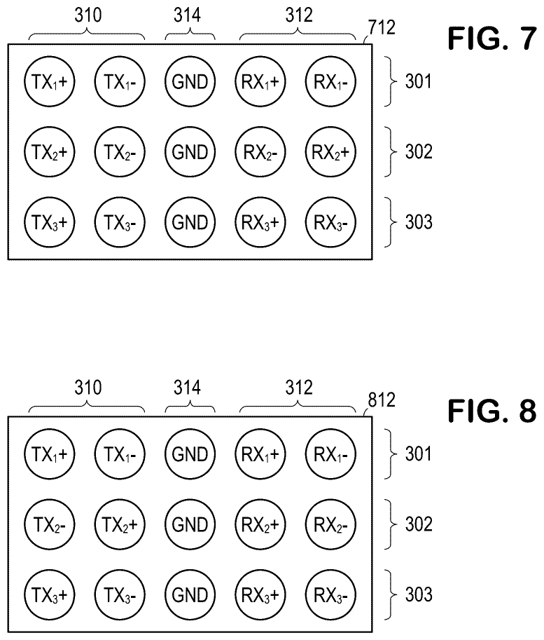

FIG. 6 is a graph of the simulation results comparing signal crosstalk in the FIG. 4B arrangement to the signal crosstalk levels in the swapped polarity arrangement of FIG. 5B. The vertical axis shows far-end crosstalk (FEXT) in decibels from 0 to −120. The horizontal axis shows signal frequency in GHz from 0 to 50. (The region of interest for current communications standards is 0 to 28 GHz.)

Line 602 shows signal crosstalk versus frequency for the FIG. 4B arrangement, while line 604 shows signal crosstalk versus frequency for the polarity-swapped arrangement of FIG. 5B. In the region of interest, the polarity-swapped arrangement demonstrates an improvement between 4 dB at the high end to 20 dB at the low end. Across most of the region of interest, the improvement exceeds 10 dB. This improvement is achievable with a signal routing change having no added manufacturing cost.

FIG. 7 shows the portion of the contact layout seen in FIG. 3 for an integrated circuit die 712 employing the described polarity-swapped configuration in which the differential transmit signal contacts for each of the lanes 301-303 have a matching signal polarity and the differential receive contacts for lane 302 have a reversed polarity relative to lanes 301, 303 to provide signal crosstalk reduction. As previously mentioned, a similar effect can be achieved with polarity swapping at the other end of the link.

FIG. 8 shows the portion of the contact layout seen in FIG. 3 for an integrated circuit die 812 employing a polarity-swapped configuration in which the differential receive signal contacts for each of the lanes 301-303 have a matching signal polarity and the differential transmit signal contacts for lane 302 have a reversed signal polarity relative to lanes 301, 303. This arrangement achieves the same reduction in signal crosstalk between lanes.

FIG. 9 is a function block diagram of an illustrative integrated circuit device 912 that supports multi-lane communication links. Device 912 may be, e.g., a retimer or link extender. Device 912 includes serializer/deserializer (SerDes) modules with differential signal contacts 920 for sending and receiving high-rate serial bitstreams across four lanes of a first communication link, additional SerDes modules with contacts 922 for conveying the high-rate serial bitstreams across four lanes of a second communication link, and core logic 924 for implementing a channel communications protocol while buffering bitstreams between the communications links. Also included are various supporting modules with corresponding contacts 926, 928, such as power regulation and distribution, clock generation, digital input/output lines for control signals, and a JTAG module for built-in self testing.

Notably the serializer modules of device 912 employ differential transmit signal contacts having matched polarities across the lanes of each communication link. To reduce signal crosstalk, however, the deserializer modules of device 912 employ differential receive signal contacts having alternate polarities that are reversed relative to the adjacent lanes of each communications link.

If local device 912 connects to similar remote devices or remote devices sharing a similar interface arrangement, the connection-induced crosstalk at the receive end of each link will have a polarity opposite the connection-induced crosstalk at the transmit end, yielding reduced signal crosstalk between lanes.

The implementations described herein may provide an advantageous solution for mitigating signal crosstalk in high-density, high-bandwidth communication links such as those commonly encountered in semiconductor wafer probe testing systems. By incorporating the polarity-swapping technique, crosstalk contributions from adjacent lanes can be effectively reduced, thus improving the signal integrity and reliability. This approach requires minimal changes to existing probe card designs and can be implemented without additional manufacturing costs. Furthermore, the described configurations are compatible with the use of SerDes transceivers and other differential signaling modules, ensuring broad applicability across various systems. The disclosed embodiments should provide greater accuracy and efficiency in wafer-level integrated circuit characterizations.

Numerous alternative forms, equivalents, and modifications will become apparent to those skilled in the art once the above disclosure is fully appreciated. Though wafer testing systems are disclosed as an illustrative context, the foregoing disclosure has applicability to any connection arrangement that may introduce signal crosstalk and opposite ends of a link. It is intended that the claims be interpreted to embrace all such alternative forms, equivalents, and modifications where applicable.

What is claimed is:

1. A system that comprises:
a first integrated circuit die having a set of differential transmit signal contacts for multiple adjacent lanes of a communications link;
a second integrated circuit die having a set of differential receive signal contacts for the multiple adjacent lanes;
a first set of connectors coupling the differential transmit signal contacts to a set of conductors; and
a second set of connectors coupling the set of conductors to corresponding differential receive signal contacts,
the first set of connectors introducing signal crosstalk of a first polarity between a first lane of the multiple adjacent lanes and a first adjacent lane of the multiple adjacent lanes, and
the second set of connectors introducing signal crosstalk of a second polarity between the first lane and the first adjacent lane,
the second polarity being opposite of the first polarity.

2. The system of claim 1,
wherein the first lane has a first connector pair, and the first adjacent lane has a first adjacent connector pair, and the first polarity corresponds to the first adjacent connector pair having an orientation that matches an orientation of the first connector pair, and
wherein the first lane has a second connector pair, and the first adjacent lane have a second adjacent connector pair, and the second polarity corresponds to the second adjacent connector pair having an orientation reversed relative to an orientation of the second connector pair.

3. The system of claim 1,
wherein the first lane has a first connector pair, and the first adjacent lane has a first adjacent connector pair, and the first polarity corresponds to the first adjacent connector pair having an orientation reversed relative to an orientation of the first connector pair, and
wherein the first lane has a second connector pair, and the first adjacent lane have a second adjacent connector pair, and the second polarity corresponds to the second adjacent connector pair having an orientation that matches an orientation of the second connector pair.

4. The system of claim 1, wherein the first set of connectors further introduces signal crosstalk of the first polarity between the first lane of the multiple adjacent lanes and a second adjacent lane of the multiple adjacent lanes, and wherein the second set of connectors further introduces signal crosstalk of the second polarity between the first lane and the second adjacent lane.

5. The system of claim 1, wherein the first integrated circuit die is also the second integrated circuit die, and wherein the set of conductors are part of a test probe card configured to provide loopback testing.

6. The system of claim 5, wherein the first set of connectors and the second set of connectors are probe needles configured to contact bumps on the first integrated circuit die.

7. The system of claim 1, wherein the first set of connectors and the second set of connectors include bumps or pins connecting the first integrated circuit die and the second integrated circuit die to printed circuit traces on a substrate.

8. An integrated circuit die that comprises:
a first pair of differential transmit signal contacts for a first lane of a communications link;
a second pair of differential receive signal contacts for the first lane of the communications link;
a first adjacent pair of differential transmit signal contacts for a second lane of the communications link adjacent to the first lane; and
a second adjacent pair differential receive signal contacts for the second lane of the communications link,
the first pair and the first adjacent pair having signal crosstalk with a first polarity, and
the second pair and the second adjacent pair having signal crosstalk with a second polarity opposite of the first polarity.

9. The integrated circuit die of claim 8, wherein the first pair of differential transmit signal contacts has a signal polarity that matches a signal polarity of the first adjacent pair of differential transmit signal contacts, and wherein the second pair of differential receive signal contacts has a signal polarity that is reversed relative to a signal polarity of the second adjacent pair of signal contacts.

10. The integrated circuit die of claim 8, wherein the first pair of differential transmit signal contacts has a signal polarity that is reversed relative to a signal polarity of the first adjacent pair of differential transmit signal contacts, and wherein the second pair of differential receive signal contacts has a signal polarity that matches a signal polarity of the second adjacent pair of signal contacts.

11. The integrated circuit die of claim 8, further comprising:
a third pair of differential transmit signal contacts for a third lane of the communications link adjacent to the first lane; and
a fourth pair of differential receive signal contacts for the third lane of the communications link,
the first pair and the third pair having signal crosstalk with the first polarity, and
the second pair and the fourth pair having signal crosstalk with the second polarity opposite of the first polarity.

12. The integrated circuit die of claim 8, comprising:
a pair of differential transmit signal contacts for each lane of the communications link, the pairs of differential transmit signal contacts having a matching signal polarity for adjacent lanes; and
a pair of differential receive signal contacts for each lane of the communications link, the pairs of receive signal contacts having opposite signal polarities for adjacent lanes.

13. The integrated circuit die of claim 8, comprising:
a pair of differential transmit signal contacts for each lane of the communications link, the pairs of differential transmit signal contacts having opposite signal polarities for adjacent lanes; and
a pair of differential receive signal contacts for each lane of the communications link, the pairs of receive signal contacts having matching signal polarities for adjacent lanes.

14. A wafer tester that comprises:
a substrate; and
a test probe head mounted on the substrate and having needles configured to connect bumps of an integrated circuit on a wafer to traces on the substrate, the bumps including:
a first pair of differential transmit signal contacts for a first lane of a communications link;
a second pair of differential receive signal contacts for the first lane of the communications link;
a first adjacent pair of differential transmit signal contacts for a second lane of the communications link adjacent to the first lane; and
a second adjacent pair differential receive signal contacts for the second lane of the communications link,
wherein the needles contacting the first pair and first adjacent pair introduce signal crosstalk of a first polarity,
wherein the needles contacting the second pair and second adjacent pair introduce crosstalk of a second polarity, and
wherein the traces on the substrate configure the second polarity to be opposite of the first polarity during loopback testing.

15. The wafer tester of claim 14, wherein the first pair of differential transmit signal contacts has a signal polarity that matches a signal polarity of the first adjacent pair of differential transmit signal contacts, and wherein the second pair of differential receive signal contacts has a signal polarity that is reversed relative to a signal polarity of the second adjacent pair of signal contacts.

16. The wafer tester of claim 14, wherein the first pair of differential transmit signal contacts has a signal polarity that is reversed relative to a signal polarity of the first adjacent pair of differential transmit signal contacts, and wherein the second pair of differential receive signal contacts has a signal polarity that matches a signal polarity of the second adjacent pair of signal contacts.

17. The wafer tester of claim 14, wherein the bumps include:
a pair of differential transmit signal contacts for each lane of the communications link, the pairs of differential transmit signal contacts having a matching signal polarity for adjacent lanes; and
a pair of differential receive signal contacts for each lane of the communications link, the pairs of receive signal contacts having opposite signal polarities for adjacent lanes.

18. The wafer tester of claim 14, wherein the bumps include:
a pair of differential transmit signal contacts for each lane of the communications link, the pairs of differential transmit signal contacts having opposite signal polarities for adjacent lanes; and
a pair of differential receive signal contacts for each lane of the communications link, the pairs of receive signal contacts having matching signal polarities for adjacent lanes.
